(19) United States
(12) Patent Application Publication
(10) Pub. No.: US 2013/0273262 A1
(43) Pub. Date: Oct. 17, 2013

(54) STATIC DEPOSITION PROFILE MODULATION FOR LINEAR PLASMA SOURCE

(71) Applicants: Manoj Vellaikal, Sunnyvale, CA (US); Michael S. Cox, Gilroy, CA (US); Hemant P. Mungekar, Campbell, CA (US); Chikuang C. Wang, San Jose, CA (US); Lin Zhang, San Jose, CA (US); Hari K. Ponnekanti, San Jose, CA (US); Michael P. Stewart, San Francisco, CA (US); Edward P. Hammond, IV, Hillsborough, CA (US); Alexander S. Polyak, San Jose, CA (US)

(72) Inventors: Manoj Vellaikal, Sunnyvale, CA (US); Michael S. Cox, Gilroy, CA (US); Hemant P. Mungekar, Campbell, CA (US); Chikuang C. Wang, San Jose, CA (US); Lin Zhang, San Jose, CA (US); Hari K. Ponnekanti, San Jose, CA (US); Michael P. Stewart, San Francisco, CA (US); Edward P. Hammond, IV, Hillsborough, CA (US); Alexander S. Polyak, San Jose, CA (US)

(73) Assignee: Applied Materials, Inc., Santa Clara, CA (US)

(21) Appl. No.: 13/447,035

(22) Filed: Apr. 13, 2012

(51) Int. Cl. C23C 16/50

(52) U.S. Cl. 427/569; 118/723 R

(57) ABSTRACT

Methods and apparatus for controlling film deposition using a linear plasma source are described herein. The apparatus include a showerhead having openings therein for flowing a gas therethrough, a conveyor to support one or more substrates thereon disposed adjacent to the showerhead, and a power source for ionizing the gas. The ionized gas can be a source gas used to deposit a material on the substrate. The deposition profile of the material on the substrate can be adjusted, for example, using a gas-shaping device included in the apparatus. Additionally or alternatively, the deposition profile may be adjusted by using an actuatable showerhead. The method includes exposing a substrate to an ionized gas to deposit a film on the substrate, wherein the ionized gas is influenced with a gas-shaping device to uniformly deposit the film on the substrate as the substrate is conveyed proximate to the showerhead.

### BACKGROUND OF THE INVENTION

1. Field of the Invention

Embodiments of the present invention generally relate to methods and apparatus for processing substrates using a linear plasma source.

2. Description of the Related Art

A linear plasma source is a stationary source of excited species which may be used to process one or more substrates moving adjacent to the source. Multiples stationary sources may be positioned in series to perform processes on substrates in a desired order. For example, multiple sources may be arranged to deposit a plurality of successive semiconductor layers on a substrate.

Substrates which are processed using a linear plasma source are moving during processing, which leads to non-uniformities across the substrate surfaces. FIG. 1A and FIG. 1B illustrate graphs 100A and 100B of film properties of materials deposited on a substrate using a conventional linear plasma source. FIG. 1A illustrates the thickness and refractive index of a film deposited on a substrate, while FIG. 1B illustrates the thickness and density for the same film graphed in FIG. 1A. The film thickness is illustrated by line 101, and the refractive index is illustrated by line 102. The density of the film is illustrated by line 103. The travel direction of the substrate during processing is indicated by arrow 104. The leading edge of the substrate (e.g., the edge of the substrate first introduced to the source) is bounded by box 105. As is shown, the film at the leading edge of the substrate has a reduced thickness as compared to the rest of the film on the substrate. Additionally, the film at the leading edge of the substrate has a reduced refractive index, which is often an indicator of lower film density (shown in FIG. 1B). The variation of the film qualities across a substrate surface negatively impacts device quality and performance.

Therefore, there is a need for a method and apparatus for controlling film deposition across the surface of a substrate when using a linear plasma source.

### SUMMARY OF THE INVENTION

Methods and apparatus for controlling film deposition in a linear plasma source are described herein. The apparatus include a showerhead having openings therein for flowing a gas therethrough, a conveyor disposed adjacent to the showerhead and adapted to support one or more substrates thereon, and a power source for ionizing the gas. The ionized gas can be a source gas used to deposit a material on the substrate. The deposition profile of the material on the substrate can be adjusted, for example, using a gas-shaping device, such as a magnet or shield. Additionally or alternatively, the deposition profile may be adjusted by using an actuatable showerhead. The method includes exposing a substrate to an ionized gas to deposit a film on the substrate, wherein the ionized gas is influenced with a gas-shaping device to uniformly deposit the film on the substrate as the substrate is conveyed proximate to the showerhead.

In one embodiment, a linear plasma source comprises a showerhead having openings formed therein for flowing a gas therethrough, and a conveyor positioned adjacent to the showerhead. The conveyor is adapted to support a substrate thereon and move the substrate relative to the showerhead. The linear plasma source further comprises a power source for ionizing the gas, and a gas-shaping device disposed proximate to the showerhead to influence a deposition profile on a substrate. The gas-shaping device is adapted to be actuated during processing.

In another embodiment, a linear plasma source comprises a showerhead having a lower surface with openings formed therein for flowing a gas therethrough, and a conveyor positioned adjacent to the showerhead. The conveyor is adapted to support a substrate thereon and move the substrate relative to the showerhead. The linear plasma source further comprises a power source for ionizing the gas, and an actuator adapted to change an angle of the lower surface of the showerhead with respect to an angle of an upper surface of the conveyor.

In another embodiment, a linear plasma source comprises a conveyor adapted to support a substrate thereon and move the substrate in a first direction, and a showerhead positioned above the conveyor. The showerhead includes isolated gas passages fluidly coupled to openings formed with the showerhead for flowing a gas therethrough. The gas flow through the showerhead is non-uniform. The linear plasma source also includes a power source for ionizing gas.

In another embodiment, a method for processing a substrate on a linear plasma source comprises disposing a substrate on a conveyor and conveying a substrate proximate to a showerhead. The substrate is then exposed to an ionized gas to deposit a film on the substrate. The ionized gas is influenced with a gas-shaping device to uniformly deposit the film on the substrate as the substrate is conveyed proximate to the showerhead.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A and FIG. 1B illustrate graphs of film properties of materials deposited on a substrate in a conventional linear plasma source.

FIG. 2 is a schematic sectional view of a linear plasma source having gas-shaping devices according to one embodiment of the invention.

FIG. 3 is a schematic sectional view of a linear plasma source having gas-shaping devices according to another embodiment of the invention.

FIG. 4 is a schematic sectional view of a linear plasma source having adjustable showerheads.

FIG. 5 is a schematic sectional view of a linear plasma source having showerheads and which have distinct gas passages therethrough.

FIG. 6A and FIG. 6B are schematic bottom views of showerheads according to embodiments of the invention.

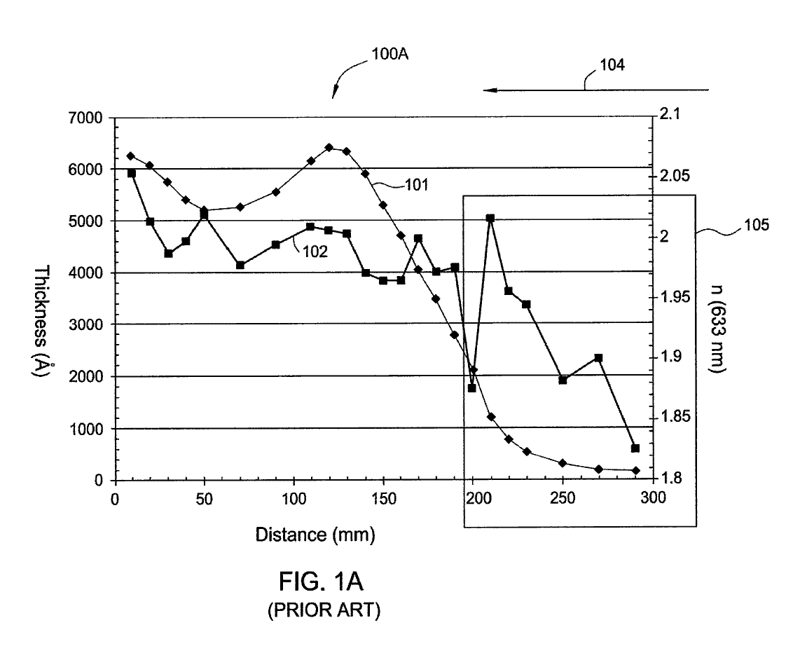

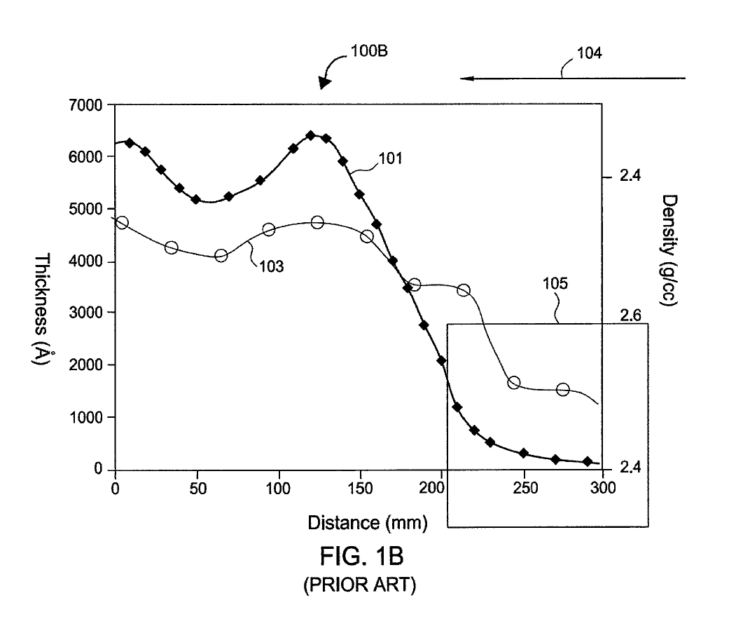

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods and apparatus for controlling film deposition using a linear plasma source are described herein. The apparatus include a showerhead having openings therein for flowing a gas therethrough, a conveyor disposed adjacent to the showerhead and adapted to support one or more substrates thereon, and a power source for ionizing the gas. The ionized gas can be a source gas used to deposit a material on the substrate. The deposition profile of the material on the substrate can be adjusted, for example, using a gas-shaping device, such as a magnet or shield. Additionally or alternatively, the deposition profile may be adjusted by using an actuatable showerhead. The method includes exposing a substrate to an ionized gas to deposit a film on the substrate, wherein the ionized gas is influenced with a gas-shaping device to uniformly deposit the film on the substrate as the substrate is conveyed proximate to the showerhead.

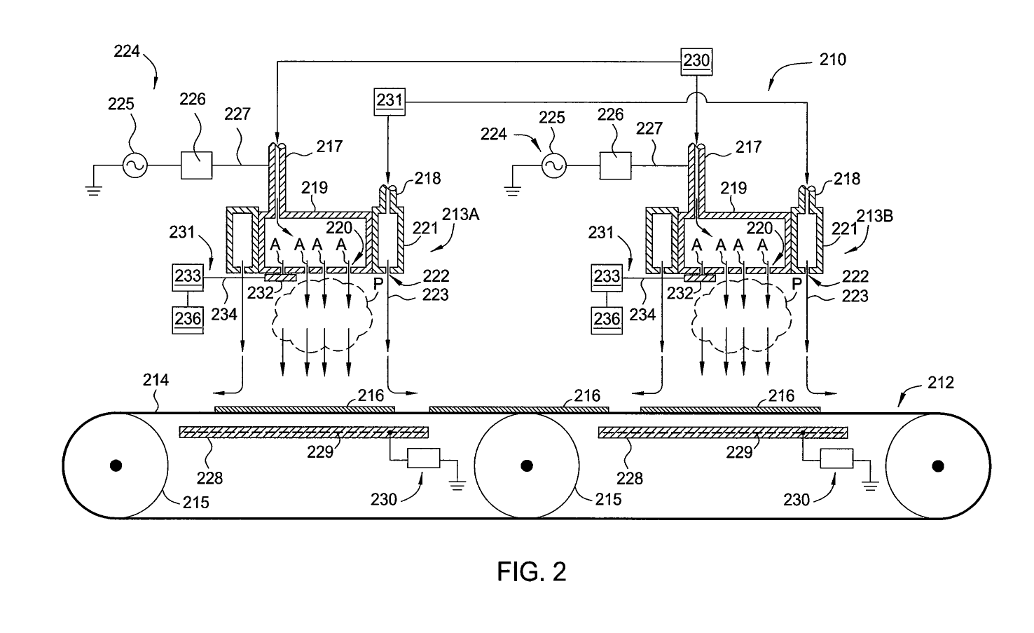

FIG. 2 is a schematic sectional view of a linear plasma source 210 having a gas-shaping device 231 according to one embodiment of the invention. The linear plasma source 210 includes a conveyor 212 and a plurality of deposition sources, such as showerheads 213A and 213B, disposed above the conveyor 212. The conveyor 212 includes a belt 214 and rollers 215 which are driven by actuators to move substrates 216 proximate to the showerheads 213A and 213B. Each of the showerheads 213A and 213B includes a first gas delivery element 217 and second gas delivery element 218. The first gas delivery elements 217 are coupled to a first gas source 230, and the second gas delivery elements 218 are coupled to a second gas source 291. The first gas delivery elements 217 deliver a first process gas, such as a precursor gas, to first plenums 219. The plenums 219 include openings 220 formed therein for delivering a gas therethrough. The gas exits the first plenums 219 through openings 220 along flow path “A” to regions adjacent to the substrates 216 to facilitate deposition of material on the substrates 216.

The second gas delivery elements 218 are in fluid communication with second plenums 221 of each of the showerheads 213A and 213B. Each of the second plenums 221 is disposed around a perimeter of a respective first plenum 219. Process gas, for example an inert gas such as argon or helium, is introduced to the second plenums 221 via the second gas delivery elements 218, and exits the second plenums 221 through openings 222 formed therein. The process gas exiting the second plenums 221 forms a gas curtain 223 which acts as a barrier to contain an ionized gas “P” therein, thus preventing deposition of material in undesired locations of the linear plasma source 210.

The ionized gas P includes or is generated from the process gas exiting the openings 220 of the first plenum 219. The ionized gas P is generated from the process gas by application of power from a power source 224. The power source includes an RF power supply 225, and optional match 226 (e.g., a matching network), and an electrical connection 227. Application of power from the power source 224 may be used to generate the ionized gas P, such as a plasma, adjacent to a substrate 216. Electrode 228 are positioned beneath the showerheads 213A and 213B on the opposite side of the belt 214 as a substrate 216 to facilitate placement of a substrate 216 near the ionized gas P. The electrode 228, which may include a heating element 229, can be electrically biased by an electrical source 290, such as an AC or DC power supply, to ground the electrode 228.

A gas-shaping device 231, such as an actuatable shield, is positioned adjacent to the lower surface of each of the showerheads 213A and 213B. The gas-shaping devices 231 include a shield 232, which is formed from a material which is inert with respect to the process gas, such as quartz, and actuators 233. The actuators 233, for example, hydraulic, pneumatic, or electrical actuators, are adapted to position the shields 232 adjacent to the surface of a respective showerhead 213A or 213B and selectively block the passage of a process gas through the openings 220. The shield 232 is dynamically actuatable during processing to adjust the amount of gas exiting the showerheads 213A and 213B, and thus, the location of the ionized gas P, or the density of the ionized gas P at certain locations. In one example, the actuation of the shield 232 may correspond to or depend upon the movement of the conveyor 212 or a substrate 216 thereon, and may be controlled by one or more controllers 236. Thus, the density of the ionized gas P can be adjusted at specific locations within the ionized gas P as a substrate 216 moves thereby, which facilitates uniform deposition on the substrate 216. The adjustable density of the ionized gas P facilitates uniform deposition by allowing for increased or decreased deposition at specific locations on the substrate 216, thereby resulting in a uniform deposition profile. Additionally, the dynamic real-time actuation of the shield 232 allows for corrections in the deposition profile on the substrate while the substrate is being moved.

The gas-shaping device 231 also includes a mechanical connection, such as a rod 234, which couples the actuator 233 to the shield 232. Generally, the diameter of the rod 234 is minimized so as not to disrupt the gas curtain 223. In one example, the shield 232 may have a flat rectangular shape, however, it is contemplated that the shield 232 may have other shapes, including arcuate or circular.

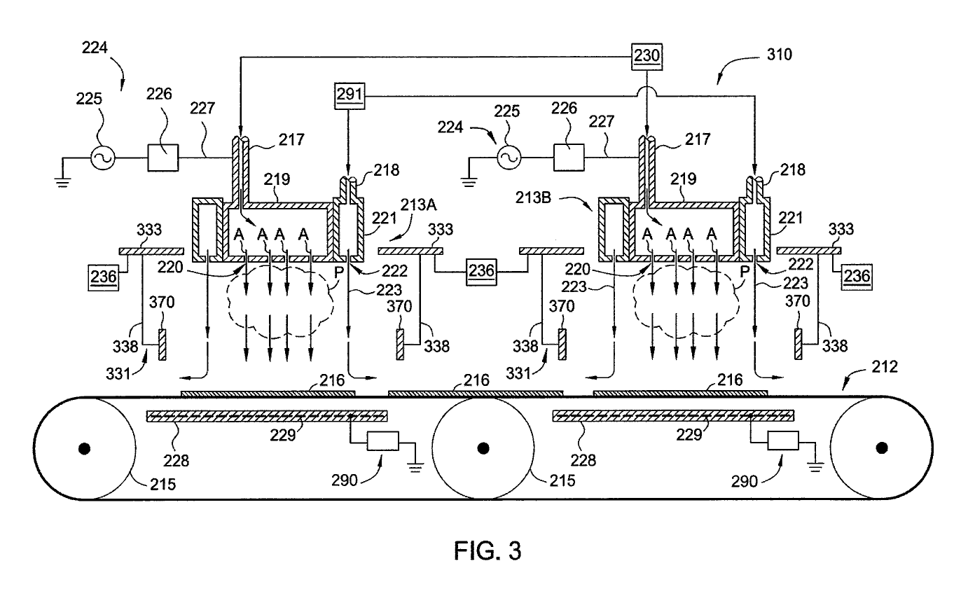

FIG. 3 is a schematic sectional view of a linear plasma source 310 having gas-shaping devices 331 according to another embodiment of the invention. The linear plasma source 310 is similar to the linear plasma source 210; however, the linear plasma source 310 includes different gas-shaping devices 331 than the gas-shaping devices 231. The gas shaping devices 331 include magnets 370 positioned proximate to each showerhead 213A and 213B. The magnets 370 are positioned beneath the lower surface of each showerhead 213A and 213B, and above the conveyor 212 adjacent to the ionized gas P. The magnets 370 are adapted to influence or shape the ionized gas P to control the density, shape, or position of the ionized gas P with respect to a substrate 216. The influence of the magnets 370 on the ionized gas P is determined by the position of the magnets 370 with respect to the ionized gas P. The position of the magnets 370 is determined by controllers 236, which are coupled to actuators 333. The actuators 333, which may include a track or guide rail system, are adapted to move the magnets 370 in X, Y, and Z positions with respect to the ionized gas P. The magnets 370 are coupled to respective actuators 333 by a linkage 338. The movement of the magnets 370 may be related to the movement of substrates 216 along the conveyor 212, so as to cause uniform processing, such as deposition, on the surface of the substrates 216 by controlling the density or location of the ionized gas P. It is contemplated that the magnets 370 may be permanent magnets, or may be electromagnets having a power supply coupled thereto.

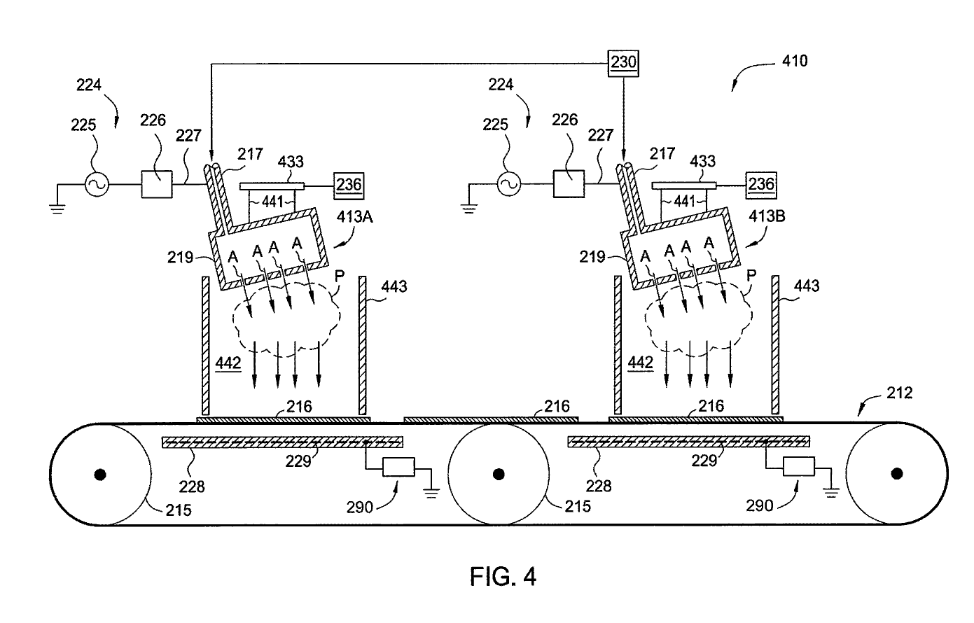

FIG. 4 is a schematic sectional view of a linear plasma source 410 having adjustable showerheads 413A and 413B. The linear plasma source 410 is similar to the linear plasma source 210, except the linear plasma source 410 manipulates the density or position of the ionized gas P using an adjustable showerhead 413A or 413B, rather than the shields 232 (shown in FIG. 2). The showerheads 413A and 413B are actuated (e.g., pivoted, tilted, or vertically moved) by actuators 433 which are coupled to the showerheads 413A and 413B by linkages 441. The length of one or both of each linkages 441 coupled to a respective showerheads 413A or 413B can be adjusted by the actuators 433 to adjust the angle or position of the showerhead 413A or 413B. Adjustment of the position of the showerheads 413A and 413B affects the proximity of the ionized gas P with respect to locations of substrates 216, and thus, the deposition profile on the surface of substrates 216. For example, moving one end of the showerheads 413A or 413B closer to a substrate 216 may result in a greater amount of deposition on the substrate 216 proximate to the lowered end of the respective showerhead 413A or 413B.

The actuators 433 are capable of adjusting the position of the showerheads 413A and 413B in real time as a substrate 216 is conveyed proximate to the showerheads 413A and 413B in order to facilitate uniform deposition on the substrates 216. Because the showerheads 413A and 413B are movable, it may be desirable to use flexible fittings or tubing to couple the first gas source 230 to the showerheads 413A and 413B, thereby allowing movement of the showerheads 413A and 413B with a reduced likelihood of gas leakage.

The showerheads 413A and 413B include only a single plenum 219. To contain the ionized gas P in desired regions 442 above the conveyor 212, a gas-containing enclosure 443 is positioned around the region 442. The gas-containing enclosure 443 is generally stationary, and formed form the same material as the showerhead assemblies 413A and 413B, such as aluminum or stainless steel. The gas-containing enclosure 443 may have a cylindrical or rectangular shape, or any other shape which is sufficient to contain the ionized gas P in the region 442.

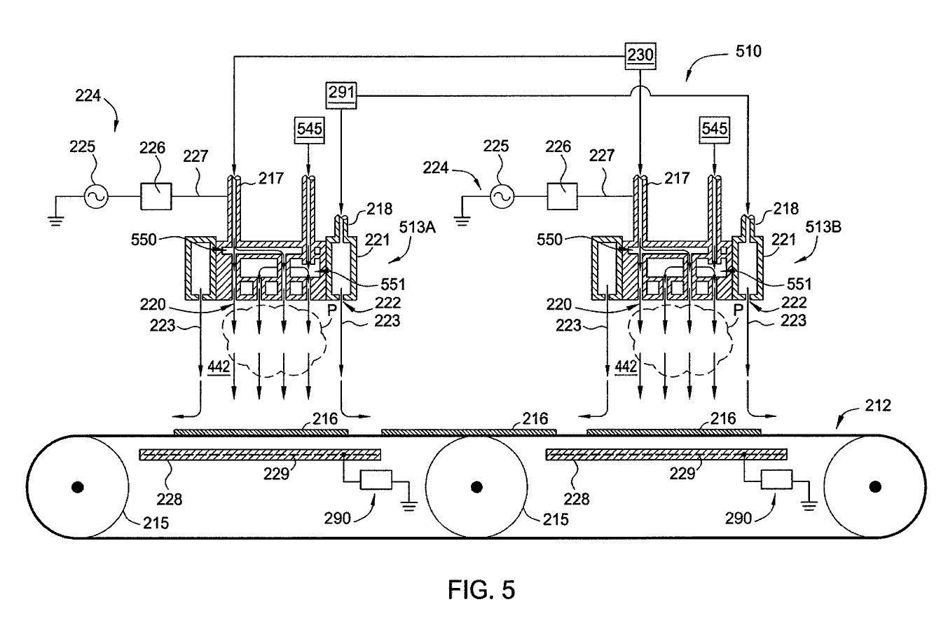

FIG. 5 is a schematic sectional view of a linear plasma source 510 having showerheads 513A and 513B which have distinct (i.e., isolated) gas passages therethrough. The linear plasma source 510 is similar to the linear plasma source 210, except the linear plasma source 510 facilitates a uniform deposition on substrates 216 using showerheads 513A and 513B, rather than a gas-shaping devices 231 (shown in FIG. 2). The showerheads 513A and 513B have isolated gas passages 550 and 551 therein, and are adapted to control the composition of regions of the ionized gas P to facilitate uniform processing of substrates. A first isolated gas passage 550 in each of the showerheads 513A and 513B is fluidly connected to the first gas source 230, while a second isolated gas passage 551 is coupled to a third gas source 545, which may supply the same or a different process gas as the first gas supply source 230. The isolated gas passages 550 and 551 allow the composition of the gas provided to a process region 442 to be controlled, since the flow rate of each gas can be individually controlled. Additionally, because the isolated gas passages 550 and 551 are fluidly connected to different openings 220, the composition of the ionized gas can be linearly controlled along the showerheads 513A and 513B, particularly in the direction of movement of the conveyor 212. For example, a greater flow rate of precursor gas may be provided to some openings 220 relative to other openings, due to the use of separate gas passages 550 and 551. Thus, the ionized gas P will have larger concentrations of precursor material at some points within the ionized gas P relative to other, thereby facilitating an increased deposition rate on a substrate at areas adjacent to the larger concentrations within the ionized gas P. Thus, the composition or density of the ionized gas P can be controlled via the isolated gas passages 550 and 551 to facilitate a uniform deposition of material on a substrate 216 by increasing or decreasing deposition rate in desired locations.

The isolated gas passages 550 and 551, as illustrated, provide process gas through alternating openings 220 formed within the showerheads 513A and 513B. However, other embodiments for controlling the composition of the ionized gas P are also contemplated. For example, it is contemplated that the first isolated gas passage 550 may provide gas to first set of gas openings 220 disposed at a first end of each showerheads 513A and 513B, while the second set of isolated gas passages 551 provide gas through openings 220 disposed at the opposite end of the showerheads 513A and 513B. In such an example, the isolated gas passages 550 and 551 can be utilized to adjust the composition of the ionized gas P linearly along the showerheads 513A and 513B. Additional configurations of the isolated gas passages 550 and 551 are also contemplated in order to adjust the composition and density of the ionized gas P, as desired. Furthermore, it is to be noted that the flow rate through each of the gas passages 550 and 551 can be adjusted during processing.

FIGS. 2-5 illustrate embodiments of linear plasma sources; however, other embodiments are also contemplated. In another embodiment, it is contemplated that the linear plasma sources 210, 310, 410, and 510 may include more than or less than two showerheads. In yet another embodiment, it is contemplated that the showerheads 213A and 213B may not include the second plenums 221. Instead, physical walls, such as a shield, formed from aluminum or stainless steel, may be utilized to contain the ionized gas P. In another embodiment, it is contemplated that the ionized gas P may be generated using an energy source other than RF power. For example, it is contemplated that the ionized gas P may be generated using an electron beam source. The electron beam source may be actuatable relative to the showerheads to dynamically adjust the density of the ionized gas P at certain locations within the ionized gas P during processing.

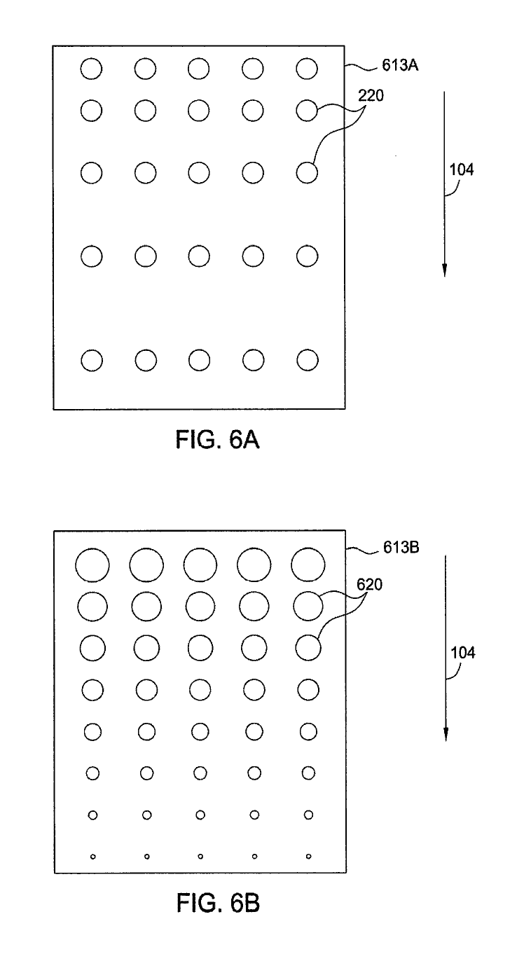

FIG. 6A and FIG. 6B are schematic bottom views of showerheads 613A and 613B according to embodiments of the invention. The showerheads 613A and 613B may be used in any of the linear plasma sources 210, 310, 410, or 510. The showerhead 613A includes a plurality of openings 220 formed in the lower surface thereof to allow for the passage of one or more gasses therethrough. The openings 220 are arranged in rows having an increasing width therebetween. The width between the rows increases in the direction of movement of a substrate as indicated by arrow 104. The showerhead 613A may be used, for example, to increase deposition on the leading edge of a substrate in order to facilitate a uniform deposition of material on a substrate. It is contemplated that the gases exiting the openings 220 in the showerhead 613A can be shaped or adjusted, for example using a gas-shaping device, to further facilitate uniform deposition. It is also contemplated that the row width may decrease in the direction of substrate movement.

The showerhead 613B includes openings 620 which are arranged in equally-spaced rows, but having a decreasing diameter in the direction of substrate movement, as indicated by arrow 104. The larger diameter openings are capable of having a higher gas flow rate therethrough, thus increasing deposition rate at the leading edge of the substrate to facilitate uniform deposition on the substrate. It is contemplated that the gases exiting the openings 620 in the showerhead 613B can be shaped or adjusted, for example using a gas-shaping device, to further facilitate uniform deposition. It is also contemplated that the openings 620 may alternatively have an increasing diameter in the direction of substrate movement.

During processing of substrates on any of the linear plasma sources 210, 310, 410, or 510, substrates are moved past a respective showerhead to deposit a material on the substrate. For example, the material may be precursor material from the ionized gas. Because the substrate is moving during the deposition process, material may not be uniformly deposited on the substrate surface. For example, even though the process parameters typically remain constant while a substrate is moved relative to a showerhead during processing, the leading edge of the substrate may experience a reduced deposition thereon with respect to the remainder of the substrate.

In order to address the problem of non-uniform processing, the linear plasma sources are adapted to adjust processing conditions (e.g., composition, position, or density of an ionized gas) real time during the deposition process. Thus, the deposition profile can be adjusted to facilitate a uniform deposition on a substrate. For example, in deposition processes which typically result in reduced amount of deposition on a substrate leading edge, the linear plasma sources 210, 310, 410, and 510 can be programmed or controlled to increase the deposition on leading edge of the substrate with respect to the remainder of the substrate. As the substrate continues to move through the linear plasma source adjacent to a showerhead, the process parameters may be adjusted to equalize the deposition on the remainder of the substrate. In such an example, the deposition of material is increased to facilitate more deposition on the leading edge of the substrate, and then reduced for the trailing edge of the substrate, thus resulting in a uniform deposition over the entire surface of the substrate. These adjustments can be made real time as the substrate moves proximate to a showerhead.

It is contemplated that uniform deposition on substrates can be effected by using a controller included within each of the linear plasma sources 210, 310, 410, and 510. The controller can be programmed with a pre-determined set of process parameters (such as the movement of gas-shaping features or the angling of a showerhead) to facilitate uniform deposition in a repeatable fashion. Having determined a control paradigm for each of linear plasma source, substrates can then be uniformly processed therein using the predetermined movement paradigm.

The embodiments above are discussed with respect to depositions on substrates. However, it is contemplated that the methods and apparatus described herein are equally applicable to other processes. For example, the embodiments herein may also apply to etching processes.

Benefits of the invention include uniform processing of moving substrates in linear plasma sources. Embodiments of the invention allow for ionized process gases to be controlled while a substrate moves relative to a deposition source, such as a showerhead. Movement of the substrates during processing results in a decreased process time, thus increasing throughput.

While the foregoing is directed to embodiments of the present invention, other and further embodiments of the invention may be devised without departing from the basic scope thereof, and the scope thereof is determined by the claims that follow.

1. A linear plasma source, comprising:
a showerhead having openings formed therein for flowing a gas therethrough;
a conveyor positioned adjacent to the showerhead, the conveyor adapted to support a substrate thereon and move the substrate relative to the showerhead;
a power source for ionizing the gas; and
a gas-shaping device disposed proximate to the showerhead to influence a deposition profile on a substrate, wherein the gas-shaping device is actuatable during processing.

2. The linear plasma source of claim 1, wherein the gas-shaping device is movable shield adapted to prevent or reduce gas flow through at least some of the openings formed within the showerhead.

3. The linear plasma source of claim 2, wherein the movable shield is actuatable to a position located between the showerhead and the conveyor.

4. The linear plasma source of claim 3, wherein the movable shield is formed from stainless steel or quartz.

5. The linear plasma source of claim 4, wherein the movable shield moves in response to movement of the conveyor.

6. The linear plasma source of claim 1, wherein the gas-shaping device comprises one or more magnets disposed proximate to the showerhead and adapted to influence the ionized gas.

7. The linear plasma source of claim 6, wherein the one or more magnets are movable in the X, Y, and Z directions.

8. The linear plasma source of claim 7, wherein the magnets move in response to movement of the conveyor.

9. A linear plasma source, comprising:
a showerhead having a lower surface with openings formed therein for flowing a gas therethrough;
a conveyor positioned adjacent to the showerhead, the conveyor adapted to support a substrate thereon and move the substrate relative to the showerhead;
a power source for ionizing the gas; and
an actuator adapted to change an angle of the lower surface of the showerhead with respect to an angle of an upper surface of the conveyor.

10. The linear plasma source of claim 9, wherein the gas is provided to the showerhead through a flexible hose or fitting.

11. The linear plasma source of claim 9, wherein the showerhead is adapted to be inclined or declined with respect to the direction of travel of the conveyor.

12. The linear plasma source of claim 11, further comprising a second showerhead disposed above the conveyor.

13. The linear plasma source of claim 9, wherein the conveyor is adapted to support a plurality of substrates thereon.

14. A linear plasma source, comprising:
a conveyor adapted to support a substrate thereon and move the substrate in a first direction;
a showerhead positioned above the conveyor, the showerhead having isolated gas passages fluidly coupled to openings formed within the showerhead for flowing a gas therethrough, wherein the gas flow through the showerhead is non-uniform; and
a power source for ionizing the gas.

15. The linear plasma source of claim 14, wherein a varying pitching of the openings along a first direction causes the non-uniform gas flow.

16. The linear plasma source of claim 14, wherein the diameter of the openings increases along a first direction.

17. The linear plasma source of claim 14, wherein the non-uniformity comprises a non-uniform gas composition.

18. The linear plasma source of claim 14, wherein the showerhead comprises a plurality of distinct gas passages therein.

19. A method for processing a substrate on a linear plasma source, comprising:
disposing a substrate on a conveyor;
conveying a substrate proximate to a showerhead;
exposing the substrate to an ionized gas to deposit a film on the substrate, wherein the ionized gas is influenced with a gas-shaping device to uniformly deposit the film on the substrate as the substrate is conveyed proximate to the showerhead.

20. The method of claim 19, wherein influencing the gas with a gas shaping device comprises moving a shield proximate to a lower surface of the showerhead to prevent or reduce gas flow therethrough.
